(19) United States
(12) Patent Application Publication
(10) Pub. No.: US 2014/0333300 A1
(43) Pub. Date: Nov. 13, 2014

(54) REGULATED MAGNETIC FLUX DENSITY FOR EXTENDED CURRENT MEASUREMENT

(71) Applicant: HAMILTON SUNDSTRAND CORPORATION, Windsor Locks, CT (US)

(72) Inventors: Gregory I. Rozman, Rockford, IL (US); Jacek F. Gieras, Glastonbury, CT (US); Steven J. Moss, Rockford, IL (US)

(73) Assignee: Hamilton Sundstrand Corporation, Windsor Locks, CT (US)

(21) Appl. No.: 13/890,388

(22) Filed: May 9, 2013

(51) Int. Cl. G01R 19/00; G01R 33/07

(52) U.S. Cl. CPC G01R 19/0092; G01R 33/07
USPC 324/251

(57) ABSTRACT

A current sensor senses a primary current in a conductor. The current sensor includes a core, a sensing device, and a magnetizing coil. The core is configured so that the primary current generates a first magnetic field concentrated in the core. A magnetic flux density of the core is established based upon the first magnetic field and a magnetic permeability of the core. The sensing device senses the magnetic flux density of the core and provides a voltage representative of the primary current. The magnetizing coil receives a magnetizing current when the primary current is greater than a threshold value. The magnetizing coil generates a coil magnetic field in response to the magnetizing current to decrease the magnetic permeability of the core.

### BACKGROUND

Solid state power controllers (SSPCs) are often used in power distribution systems to protect electrical systems from overload conditions. SSPCs often employ ht over-current protection. ht protection allows over-currents for a short amount of time based upon a threshold power flow. These over-currents may be, for example, 800% to 1000% of the steady-state current. Because of this, the SSPCs are required to have a high accuracy current sensor with a wide measuring range. For example, if a steady-state current is 200 amps, the current sensor must be able to accurately sense up to 2000 amps.

In the past, resistive shunts and Hall effect sensors have been used for current sensing in SSPCs. Resistive shunts, however, have power losses that can be quite high when required to support large over-currents. Hall effect sensors are non-contact sensors that sense current based upon a magnetic field created by current flowing in a conductor. These sensors include a core that is implemented around the conductor in which most of the magnetic field generated by the current is concentrated. The core includes an air gap that includes a Hall effect device. The Hall effect device is mounted in the air gap of the core at a right angle to the concentrated magnetic field. The Hall effect device produces a voltage that is proportional to the current in the conductor. The larger the current in the conductor, the larger the size of the Hall effect sensor that is required in order to provide accurate measurements. It is desirable to limit the size of these current sensors in order to reduce the size and weight of the SSPC.

### SUMMARY

A current sensor senses a primary current in a conductor. The current sensor includes a core, a sensing device, and a magnetizing coil. The core is configured so that the primary current generates a first magnetic field concentrated in the core. A magnetic flux density of the core is established based upon the first magnetic field and a magnetic permeability of the core. The sensing device senses the magnetic flux density of the core and provides a voltage representative of the primary current. The magnetizing coil receives a magnetizing current when the primary current is greater than a threshold value. The magnetizing coil generates a coil magnetic field in response to the magnetizing current to decrease the magnetic permeability of the core.

### BRIEF DESCRIPTION OF THE DRAWINGS

FIG. 1 is a circuit diagram illustrating a system for sensing current utilizing regulated magnetic flux density.

FIG. 2 is a cross-sectional view illustrating a current sensor that utilizes regulated magnetic flux density.

### DETAILED DESCRIPTION

A current sensor is disclosed herein utilizing regulated magnetic flux density for extended measuring range. The current sensor is implemented to sense a primary current in a conductor. The current in the conductor produces a magnetic field that is concentrated in a core of the current sensor. A Hall effect device is mounted within an air gap of the core. The Hall effect device produces an output voltage based upon a magnetic flux density of the core. This output voltage is directly proportional to the current in the conductor.

During overload conditions, the magnetic flux density in the core can become too great for the Hall effect device to function properly. During these overload conditions, a magnetizing current is provided to a magnetizing coil to generate a magnetic field. This field is provided to the core of the current sensor to decrease the permeability of the core. By decreasing the permeability, the flux density in the core for a given magnetic field generated by the primary current is decreased. Because the fields generated by over-currents do not produce as great of a flux density in the core, the Hall effect device can function properly without saturation during overload conditions. By decreasing the permeability of the core, the coefficient of proportionality between the output of the Hall effect device and the primary current is changed. Knowing the change in the coefficient of proportionality between the output of the Hall effect device and the primary current, the primary current can be sensed during both steady-state conditions and overload conditions.

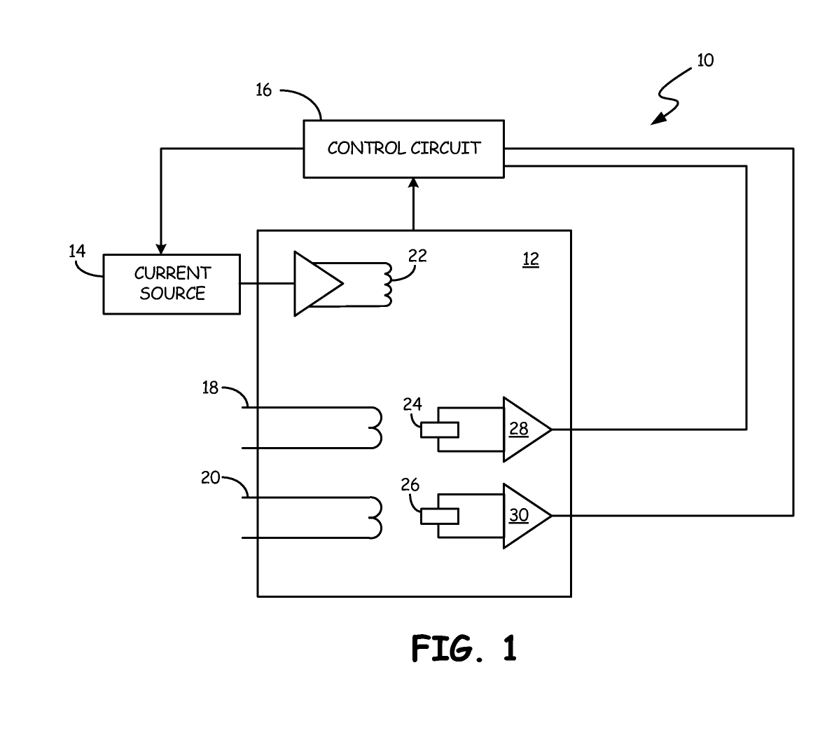

FIG. 1 is a circuit diagram illustrating system 10 for sensing current utilizing regulated magnetic flux density. System 10 may be any system that senses current such as, for example, a solid state power controller (SSPC). System 10 includes current sensor 12, current source 14, control circuit 16, and conductors 18 and 20. Current sensor 12 includes magnetizing coil 22, Hall effect devices 24 and 26, and differential amplifiers 28 and 30. Although illustrated as a dual current sensor monitoring current in two conductors 18 and 20, current sensor 12 may be implemented to monitor current in a single conductor. The two conductors 18 and 20 may be, for example, positive and negative power rails monitored by an SSPC, or may be the same conductor passed through current sensor 12 twice for increased sensitivity.

Control circuit 16 controls current from current source 14 to magnetizing coil 22. When the currents in conductors 18 and 20 are at steady-state conditions such as, for example, two hundred amps, no current is provided to magnetizing coil 22. During overload conditions, when the current in either conductor 18 or 20 is at, for example, 200% to 1000% of the steady-state current, control circuit 16 controls current source 14 to provide a magnetizing current to magnetizing coil 22. Control circuit 16 is any circuit capable of controlling current from current source 14 based upon the outputs of Hall effect devices 24 and 26. Current source 14 is any electric circuit capable of providing at least two values of current. Current source 14 may be controlled using, for example, a switch. When the switch is not conducting, current source 14 provides zero current. When the switch is conducting, current source 14 provides a current such as, for example, one amp.

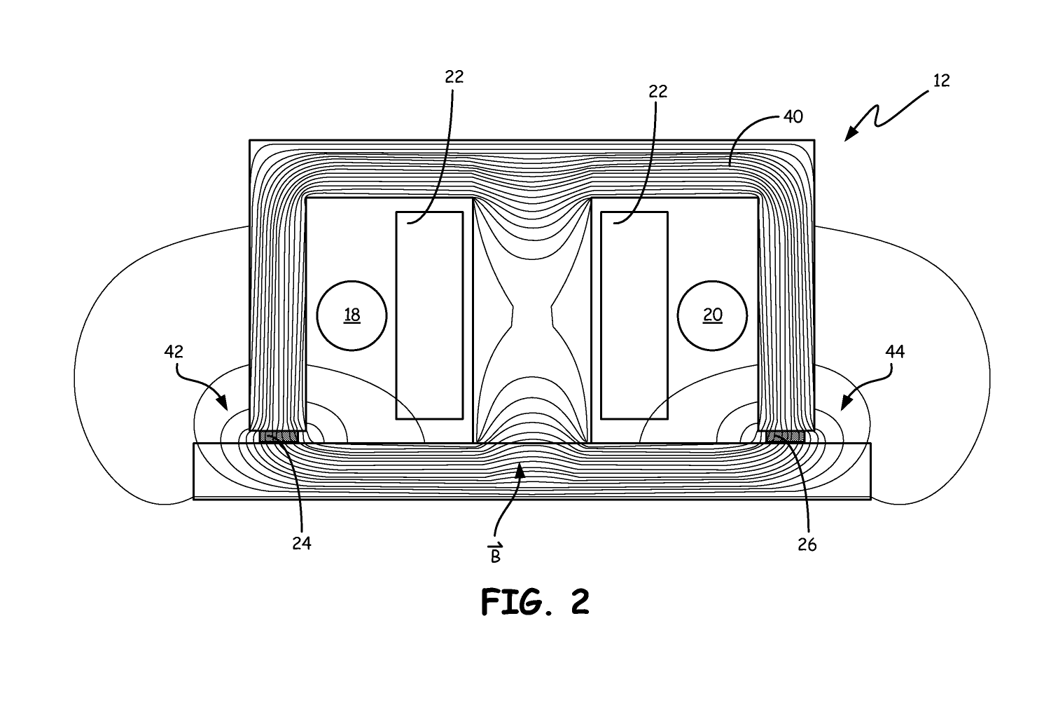

FIG. 2 is a cross-sectional view illustrating current sensor 12 that utilizes regulated magnetic flux density. Current sensor 12 includes magnetizing coil 22, Hall effect devices 24 and 26, core 40, and air gaps 42 and 44. A magnetic field (H) is generated by the current in primary conductors 18 and 20. The field (H) is concentrated in core 40 and is related to the magnetic flux density (B) of core 40 by the following equation:

B=μμ₀ H (Eq. 1)

Where:

B=magnetic flux density;

H 32 magnetic field;

μ=relative permeability of core 40; and

μ₀=permeability of free space.

Hall effect devices 24 and 26 are mounted in respective air gaps 42 and 44 perpendicular to the magnetic flux density (B) of core 40. Hall effect devices 24 and 26 produce an output voltage proportional to the magnetic flux density (B). These output voltages of Hall effect devices 24 and 26 are directly proportional to the currents in respective conductors 18 and 20 with a coefficient of proportionality (k_{H}), which is based upon the following equation:

V_{H}=k_{H}I_{H} (Eq. 2)

Where:

I_{H}=current in the conductor; and

V_{H}=output voltage of the respective Hall effect device.

During steady-state operation, the current in magnetizing coil 22 is at a first value, such as zero. When zero current is provided to magnetizing coil 14, the relative permeability (μ) of core 40 is at a first permeability value. This value is any value, and is based upon the material of core 40. Core 40 is made of any suitable material such as, for example, a ferromagnetic material. When no current is provided to magnetizing coil 22, the coefficient of proportionality (k_{H}) between the output of Hall effect devices 24 and 26 and the currents in conductors 18 and 20 is at a first value. This value is based in part upon the relative permeability (μ) of core 40. During steady-state conditions, control circuit 16 of FIG. 1 determines the current in conductors 18 and 20 based upon the output voltages of Hall effect devices 24 and 26 along with the first value of the coefficient of proportionality (k_{H}). The coefficient of proportionality (k_{H}) may be determined by, for example, testing of current sensor 12.

During overload conditions, when the current in either primary conductor 18 or 20 is, for example, 200% to 1000% of the steady-state current, a magnetizing current is provided to magnetizing coil 22. During overload conditions, with no current provided to magnetizing coil 22, the flux density (B) in air gaps 42 and 44 may exceed the range of values for which Hall effect devices 24 and 26 function properly. Because of this, current sensor 12 cannot accurately sense these larger currents. When the magnetizing current is provided to magnetizing coil 22, a magnetic field is generated by coil 22 and provided to core 40. Magnetizing coil 22 may be implemented around a portion of core 40 and includes any number of turns. The magnetic field from coil 22 causes the relative permeability (μ) of core 40 to decrease from the first permeability value to a second permeability value. This second value is any value less than the first permeability value and is based upon the current to magnetizing coil 22 and the material of core 40.

By lowering the relative permeability of core 40, the respective flux density (B) of core 40 is lowered for a given field (H) generated by currents in conductors 18 or 20. By reducing the permeability, and in turn decreasing the flux density (B) for a given field (H), the flux density (B) for over-current conditions is within the range of values for which Hall effect devices 24 and 26 function properly. This way, currents can be accurately sensed by current sensor 12 without using magnetic shunts, creating variable air gaps, or using other methods of reducing the magnetic flux density (B). This change in permeability causes a change in the coefficient of proportionality (k_{H}) between Hall effect sensors 24 and 26 and the currents in conductors 18 and 20 from the first value to a second value. Therefore, during overload conditions, when a magnetizing current is provided to magnetizing coil 22, control circuit 16 can determine the current in conductors 18 and 20 based upon the second value for the coefficient of proportionality (k_{H}). The second value of the coefficient of proportionality (k_{H}) may be determined based upon, for example, testing of current sensor 12.

By decreasing the permeability of core 40 based upon the current in conductors 18 and 20, the size, weight and cost of current sensor 12 can be reduced for applications that require accurate sensing of both steady-state currents and over-currents up to, for example, 1000% of the steady-state current. While illustrated as a dual current sensor, current sensor 12 may also be implemented to sense a current in a single conductor.

The following are non-exclusive descriptions of possible embodiments of the present invention.

A current sensor that senses a first current in a first conductor includes, among other things: a core, a first sensing device, and a magnetizing coil. The core is configured so that the first current generates a first magnetic field concentrated in the core. A magnetic flux density of the core is established based upon the first magnetic field and a magnetic permeability of the core. The first sensing device senses the magnetic flux density of the core and provides a first voltage representative of the first current. The magnetizing coil receives a magnetizing current when the first current is greater than a threshold value. The magnetizing coil generates a coil magnetic field in response to the magnetizing current to decrease the magnetic permeability of the core.

The current sensor of the preceding paragraph can optionally include, additionally and/or alternatively, any one or more of the following features, configurations and/or additional components:

The current sensor senses a second current in a second conductor. The second current generates a second magnetic field concentrated in the core. The magnetic flux density of the core is further established based upon the second magnetic field.

A second sensing device senses the magnetic flux density of the core and provides a second voltage representative of the second current. The magnetizing coil receives the magnetizing current when either the first current or the second current is greater than the threshold value.

The first and second sensing devices are Hall effect devices.

The magnetizing current is received from a current source. The current source is controlled by a control circuit based upon the voltage representative of the first current.

A method includes, among other things: concentrating in a core of a current sensor a first magnetic field generated by a first primary current. A magnetic flux density of the core is established based upon the first magnetic field and a permeability of the core. The method further includes sensing the first primary current using a first sensing device of the current sensor based upon a first coefficient of proportionality between an output voltage of the first sensing device and the first primary current, providing a magnetizing current to a magnetizing coil if the first primary current is greater than a threshold value, wherein the magnetizing coil produces a coil magnetic field in response to the magnetizing current that lowers the permeability of the core, and sensing the first primary current using the first sensing device of the current sensor based upon a second coefficient of proportionality between the output voltage of the first sensing device and the first primary current when the first primary current is greater than the threshold value.

The method of the preceding paragraph can optionally include, additionally and/or alternatively, any one or more of the following features, configurations and/or additional components:

Concentrating in the core of the current sensor a second magnetic field generated by a second primary current. The magnetic flux density of the core is further established based upon the second magnetic field.

Sensing the second primary current using a second sensing device of the current sensor based upon the first coefficient of proportionality.

Providing the magnetizing current further includes providing the magnetizing current to the magnetizing coil if the second primary current is greater than the threshold value.

Sensing the second primary current using the second sensing device of the current sensor based upon the second coefficient of proportionality when either the first primary current or the second primary current is greater than the threshold value.

The first and second sensing devices are Hall effect devices.

A system includes, among other things: a current sensor, and a control circuit. The current sensor senses a first current and includes a core, a first sensing device, and a magnetizing coil. The core is configured so that the first current generates a first magnetic field concentrated in the core. A magnetic flux density of the core is established based upon the first magnetic field and a magnetic permeability of the core. The first sensing device senses the magnetic flux density of the core and provides a first voltage representative of the first current. The magnetizing coil receives a magnetizing current when the first current is greater than a threshold value. The magnetizing coil generates a coil magnetic field in response to the magnetizing current to decrease the magnetic permeability of the core. The control circuit determines the first current based upon the output voltage of the first current sensor and provides the magnetizing current to the magnetizing coil when the primary current is greater than a threshold value.

The system of the preceding paragraph can optionally include, additionally and/or alternatively, any one or more of the following features, configurations and/or additional components:

The current sensor senses a second current in a second conductor. The second current generates a second magnetic field concentrated in the core. The magnetic flux density of the core is further established based upon the second magnetic field.

The current sensor further includes a second sensing device that senses the magnetic flux density of the core and provides a second voltage representative of the second current. The magnetizing coil receives the magnetizing current when either the first current or the second current is greater than the threshold value.

The first and second sensing devices are Hall effect devices.

The control circuit provides the magnetizing current to the magnetizing coil from a current source.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A current sensor for sensing a first current in a first conductor, the current sensor comprising:
a core configured so that the first current generates a first magnetic field concentrated in the core, wherein a magnetic flux density of the core is established based upon the first magnetic field and a magnetic permeability of the core;
a first sensing device that senses the magnetic flux density of the core and provides a first voltage representative of the first current; and
a magnetizing coil that receives a magnetizing current when the first current is greater than a threshold value, wherein the magnetizing coil generates a coil magnetic field in response to the magnetizing current to decrease the magnetic permeability of the core.

2. The current sensor of claim 1, wherein the current sensor senses a second current in a second conductor, and wherein the second current generates a second magnetic field concentrated in the core, and wherein the magnetic flux density of the core is further established based upon the second magnetic field.

3. The current sensor of claim 2, further comprising:
a second sensing device that senses the magnetic flux density of the core and provides a second voltage representative of the second current; and
wherein the magnetizing coil receives the magnetizing current when either the first current or the second current is greater than the threshold value.

4. The current sensor of claim 3, wherein the first and second sensing devices are Hall effect devices.

5. The current sensor of claim 1, wherein the magnetizing current is received from a current source, and wherein the current source is controlled by a control circuit based upon the voltage representative of the first current.

6. A method comprising:
concentrating in a core of a current sensor a first magnetic field generated by a first primary current, wherein a magnetic flux density of the core is established based upon the first magnetic field and a permeability of the core;
sensing the first primary current using a first sensing device of the current sensor based upon a first coefficient of proportionality between an output voltage of the first sensing device and the first primary current;
providing a magnetizing current to a magnetizing coil if the first primary current is greater than a threshold value, wherein the magnetizing coil produces a coil magnetic field in response to the magnetizing current that lowers the permeability of the core; and
sensing the first primary current using the first sensing device of the current sensor based upon a second coefficient of proportionality between the output voltage of the first sensing device and the first primary current when the first primary current is greater than the threshold value.

7. The method of claim 6, further comprising concentrating in the core of the current sensor a second magnetic field generated by a second primary current, wherein the magnetic flux density of the core is further established based upon the second magnetic field.

8. The method of claim 7, further comprising sensing the second primary current using a second sensing device of the current sensor based upon the first coefficient of proportionality.

9. The method of claim 8, wherein providing the magnetizing current further comprises providing the magnetizing current to the magnetizing coil if the second primary current is greater than the threshold value.

10. The method of claim 9, further comprising sensing the second primary current using the second sensing device of the current sensor based upon the second coefficient of proportionality when either the first primary current or the second primary current is greater than the threshold value.

11. The method of claim 10, wherein the first and second sensing devices are Hall effect devices.

12. A system comprising:
a current sensor that senses a first current, the current sensor comprising:
a core configured so that the first current generates a first magnetic field concentrated in the core, wherein a magnetic flux density of the core is established based upon the first magnetic field and a magnetic permeability of the core;
a first sensing device that senses the magnetic flux density of the core and provides a first voltage representative of the first current; and
a magnetizing coil that receives a magnetizing current when the first current is greater than a threshold value, wherein the magnetizing coil generates a coil magnetic field in response to the magnetizing current to decrease the magnetic permeability of the core; and
a control circuit that determines the first current based upon the output voltage of the first current sensor and provides the magnetizing current to the magnetizing coil when the primary current is greater than a threshold value.

13. The system of claim 12, wherein the current sensor senses a second current in a second conductor, and wherein the second current generates a second magnetic field concentrated in the core, and wherein the magnetic flux density of the core is further established based upon the second magnetic field.

14. The system of claim 13, wherein the current sensor further comprises:
a second sensing device that senses the magnetic flux density of the core and provides a second voltage representative of the second current; and
wherein the magnetizing coil receives the magnetizing current when either the first current or the second current is greater than the threshold value.

15. The system of claim 14, wherein the first and second sensing devices are Hall effect devices.

16. The system of claim 12, wherein the control circuit provides the magnetizing current to the magnetizing coil from a current source.
